(19) United States
(12) Patent Application Publication
(10) Pub. No.: US 2025/0293172 A1
(43) Pub. Date: Sep. 18, 2025

(54) SEMICONDUCTOR PACKAGE WITH BRIDGE DIE OVER EMBEDDED INTERPOSER

(71) Applicant: Intel Corporation, Santa Clara, CA (US)

(72) Inventors: Benjamin T. Duong, Phoenix, AZ (US); Soham Agarwal, Chandler, AZ (US); Gang Duan, Chandler, AZ (US); Jeremy Ecton, Gilbert, AZ (US); Kari Hernandez, Phoenix, AZ (US); Brandon C. Marin, Gilbert, AZ (US); Pratyush Mishra, Tempe, AZ (US); Pratyasha Mohapatra, Hillsboro, OR (US); Suddhasattwa Nad, Chandler, AZ (US); Srinivas Venkata Ramanuja Pietambaram, Chandler, AZ (US)

(73) Assignee: Intel Corporation, Santa Clara, CA (US)

(21) Appl. No.: 18/603,547

(22) Filed: Mar. 13, 2024

(51) Int. Cl. H01L 23/538; H01L 23/00

(52) U.S. Cl. CPC H01L 23/5389; H01L 23/5386; H01L 24/08; H01L 24/16; H01L 24/32; H01L 24/73; H01L 2224/08225; H01L 2224/16145; H01L 2224/16227; H01L 2224/32225; H01L 2224/73204

(57) ABSTRACT

A microelectronic assembly includes a substrate with a first substrate face and a second substrate face opposite the first substrate face. An interposer is in the substrate. The interposer has a first interposer face facing the first substrate face and a second interposer face facing the second substrate face. A bridge die is over the interposer. The bridge die has a first bridge die face facing the second interposer face and a second bridge die face facing the second substrate face. A first set of electrical connections is between the first bridge die face and the second interposer face, and a second set of electrical connections is between the first interposer face and the substrate. The second set of electrical connections has a greater number of electrical connections than the first set of electrical connections.

### BACKGROUND

Integrated circuit (IC) devices (e.g., dies) can be coupled together in a multi-die IC package to integrate features or functionality and to facilitate connections to other components, such as package substrates. IC packages may include an embedded multi-die interconnect bridge (EMIB) for coupling two or more IC dies.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a side, cross-sectional view of an example microelectronic assembly, in accordance with some embodiments.

FIG. 1B is an example zoomed view of a portion of FIG. 1A, in accordance with some embodiments.

FIG. 1C is a side, cross-sectional view of an example interposer, in accordance with some embodiments.

FIG. 1D is a plan view of components illustrated in the zoomed view of FIG. 1B, in accordance with some embodiments.

FIGS. 2A-2D are cross-sectional views of example interposers, in accordance with various embodiments.

FIG. 3 is a flow diagram of an example process for manufacturing the microelectronic assembly of FIG. 1A, in accordance with some embodiments.

FIGS. 4A-4G are side, cross-sectional views of various stages in an example process for manufacturing the microelectronic assembly of FIG. 1A, in accordance with some embodiments.

FIG. 5 is a top view of a wafer and dies that may be included in a microelectronic assembly, in accordance with any of the embodiments disclosed herein.

FIG. 6 is a cross-sectional side view of an example IC device that may be included in a microelectronic assembly, in accordance with any of the embodiments disclosed herein.

FIG. 7 is a cross-sectional side view of an example IC device assembly that may include a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

Scaling of features in ICs has been a driving force behind an ever-growing semiconductor industry and emerging applications in fields such as big data, artificial intelligence, mobile communications, and autonomous driving. Scaling to smaller and smaller features enables increased densities of functional units on the limited real estate of semiconductor chips. For example, shrinking transistor size allows incorporation of an increased number of memory or logic devices on a chip, leading to the fabrication of products with increased capacity. The drive for the ever-increasing capacity, however, is not without issue. The necessity to optimize fabrication and performance of each component (e.g., of each transistor) is becoming increasingly significant.

Parallel to optimizations at the transistor level, advanced IC packaging landscape is rapidly evolving to accommodate performance expectations and requirements of shrinking transistor size. Multiple IC dies are now commonly coupled together in a multi-die IC package to integrate features or functionality and to facilitate connections to other components, such as package substrates. For example, IC packages may include an EMIB for coupling two or more IC dies.

Using an EMIB to couple IC dies has benefits, but adds additional complexities to the design and manufacture of a semiconductor package. An EMIB is typically deposited in a cavity formed in a substrate of an IC package. In some cases, the EMIB includes conductive features on a bottom face of the EMIB (e.g., facing the bottom of the cavity in the substrate), where the conductive features may be used to, for example, allow for backside power delivery to the EMIB and/or through the EMIB to dies joined to the front side of the EMIB. These conductive features on the back side of the EMIB are joined to corresponding conductive features in the substrate (for example, through formation of bonds (such as solder bonds) between the EMIB and the substrate). Alignment of conductive features of the EMIB and the substrate can be challenging, particularly if a large number of small or tightly pitched conductive features must be joined.

Furthermore, a semiconductor package can include one or more voltage regulators to, for example, decrease a voltage of an electrical current (e.g., electrical power) from a standard voltage (e.g., a 12V input voltage) to one or more operating voltages (e.g., smaller than 12V, such as 0.8V, 1.8V, 3.3V, or 5V) of, for example, IC dies coupled to the EMIB. In some cases, voltage regulators in the semiconductor package may be distant from the EMIB, or distant from the IC dies. Relaying power along a long distance between a voltage regulator and the EMIB or dies coupled to the EMIB leads to power losses and generation of waste heat. It is desirable to locate voltage regulators close to the EMIB and/or IC dies to reduce distances that currents travel to supply power to die circuitry, thereby minimizing power loss and generation of waste heat.

As described herein, an interposer is included in a substrate of an IC package. The interposer may be coupled to an EMIB, and in particular, to a lower side or back side of the EMIB (e.g., the side opposite the side that is joined to the dies over the substrate). A first set of conductive features along a first side of the interposer (e.g., a lower side or back side of the interposer) can be joined to a second set of conductive features in the substrate, and conductive features along a second, opposing side of the interposer (e.g., a top side or front side of the interposer) can be joined to conductive features in the EMIB. A number of conductive features in the first set of conductive features (e.g., between the interposer and the substrate) can be less than a number of conductive features in the second set of conductive features (e.g., between the interposer and the EMIB); furthermore, the connections between the interposer and the substrate may be wider and/or at greater pitch than the connections between the interposer and the EMIB. This allows for reduces error or mismatch during alignment and bonding or joining between the interposer (e.g., the first set of conductive features) and the conductive features in the substrate.

The material of the interposer may be selected to allow for utilization of well-established high throughput or high yield fabrication technologies (e.g., in the case of an interposer including silicon), and/or for efficient regulation of high voltages (e.g., 5V or greater) close to the EMIB (e.g., in the case of an interposer including gallium and nitrogen, such as gallium nitride, or an interposer including silicon and carbon, such as silicon carbide). The interposer may include a redistribution layer. The redistribution layer can include conductive features that join conductive features of the first set of conductive features (e.g., between the interposer and the substrate) and second set of conductive features (e.g., between the interposer and the EMIB). In particular, the conductive features in the redistribution layer can join conductive features in the first set and in the second set that correspond to select voltages (e.g., 0.8V, 1.8V, 3.3.V, or another select voltage). Advantageously, through the redistribution layer, the joining of corresponding conductive features in the first and second sets of conductive features may be performed even if the corresponding conductive features in the first and second sets are not directly aligned along opposed faces of the interposer, allowing for design flexibility.

The interposer may include a power management integrated circuit (PMIC) or another feature with power management functionality. For example, the interposer may include voltage regulation circuitry or components, such as a capacitor, an inductor, or a resistor. The voltage regulation circuitry may include a voltage step-down converter or DC-to-DC converter, such as a buck converter. The inclusion of power management functionality in the interposer (e.g., as one or more discrete or integrated components) may allow for electrical power of a desired voltage (e.g. 0.8V, 1.8V, 3.3V, 5.0V, or another desired voltage) to be relayed to electronic components such as IC dies after being, for example, stepped down from a source voltage (e.g., 12V, or another source voltage) in the interposer. The proximity of the power management functionality in the interposer to the EMIB can allow for power to be efficiently relayed to the EMIB and/or to IC dies coupled to the EMIB, with reduced power loss and generation of waste heat.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques may exhibit rounded corners, surface roughness, and other features. It is to be understood that such schematic illustrations may not reflect real-life process limitations which may cause the features to not look so “ideal” when any of the structures described herein are examined using, e.g., output of suitable characterization tools such as scanning electron microscopy (SEM) images, transmission electron microscope (TEM) images, or non-contact profilometer data. In such output of suitable characterization tools or images of real structures, possible processing and/or surface defects or features could also be visible, e.g., surface roughness, curvature or profile deviation, pits or scratches, not-perfectly straight edges of materials, tapered vias or other openings, inadvertent rounding of corners or variations in thicknesses of different material layers, occasional screw, edge, or combination dislocations within one or more crystalline regions, and/or occasional dislocation defects of single atoms or clusters of atoms. There may be other defects not listed here but that are common within the field of device fabrication and/or packaging.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.” Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner. The term “circuit” means one or more passive and/or active components that are arranged to cooperate with one another to provide a desired function. The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

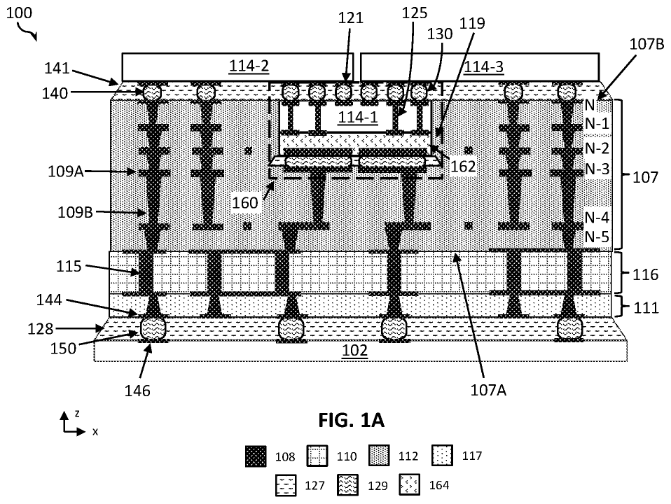

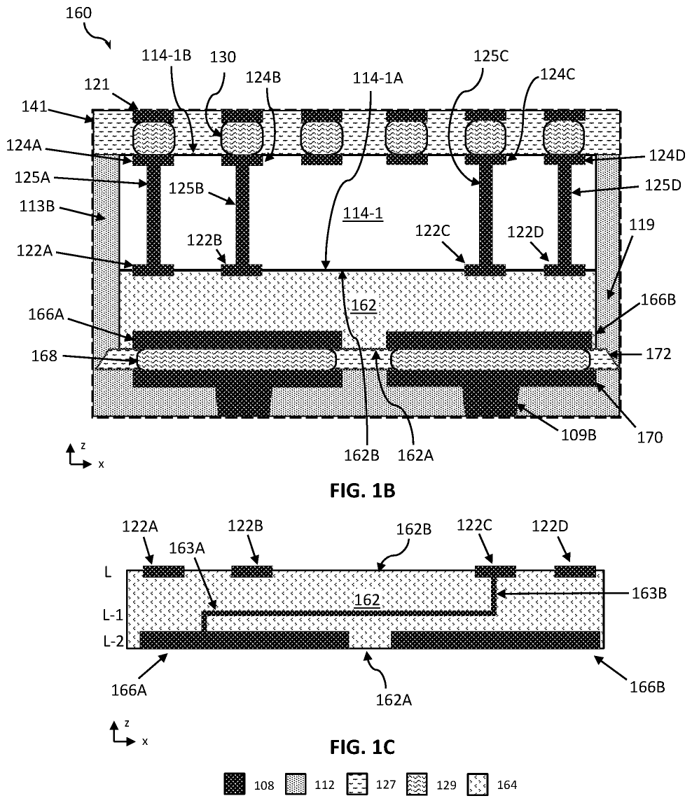

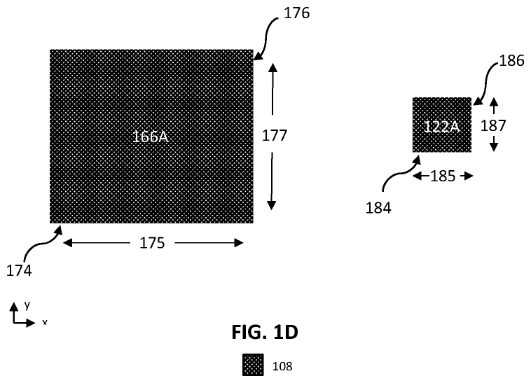

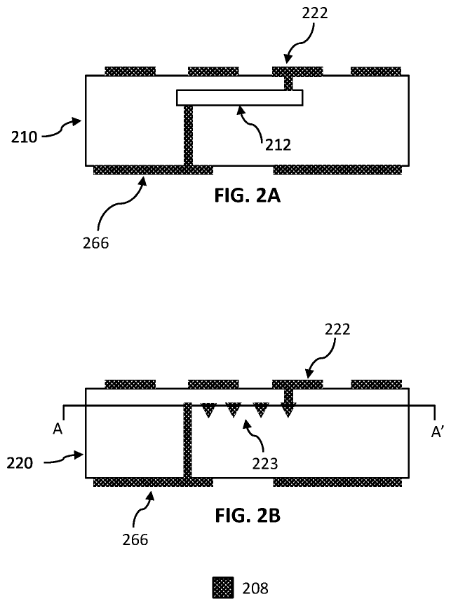

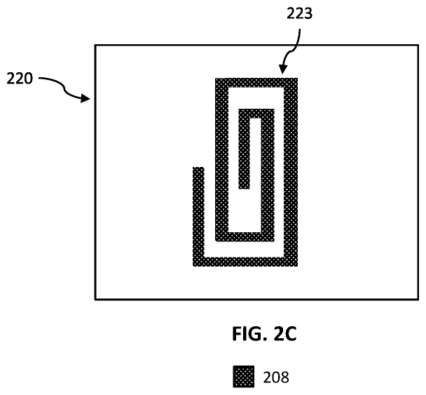

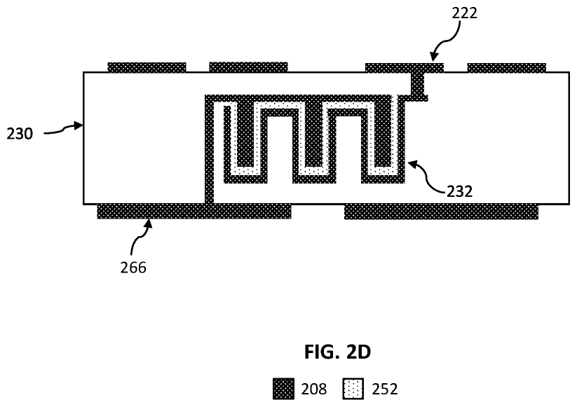

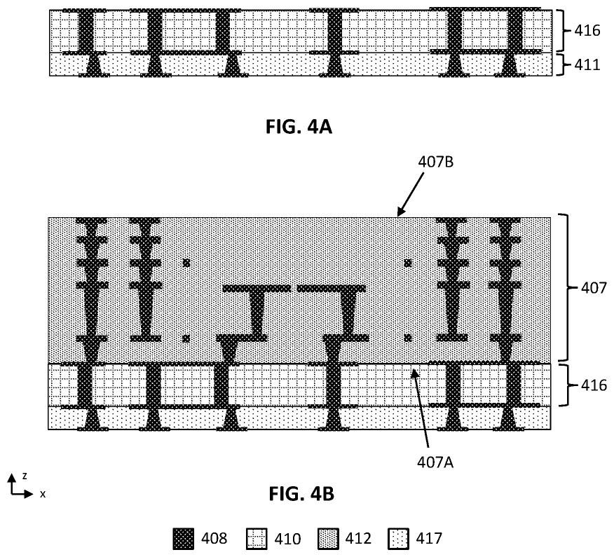

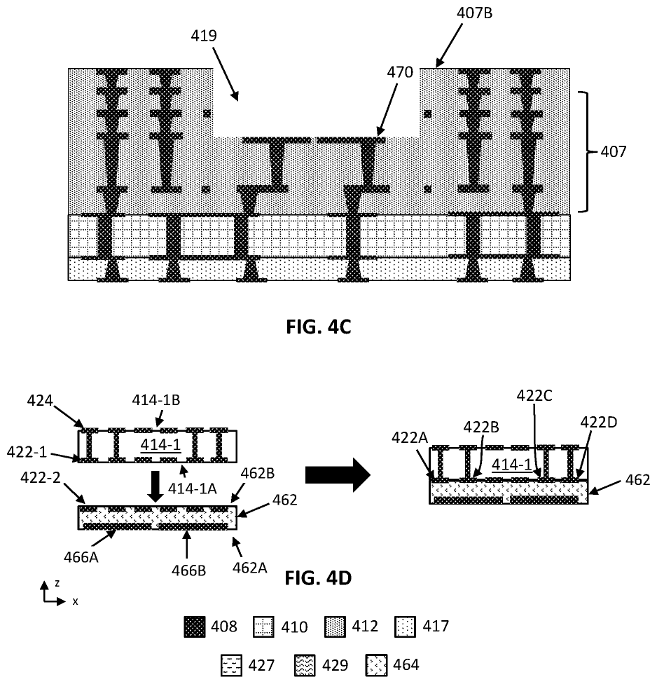

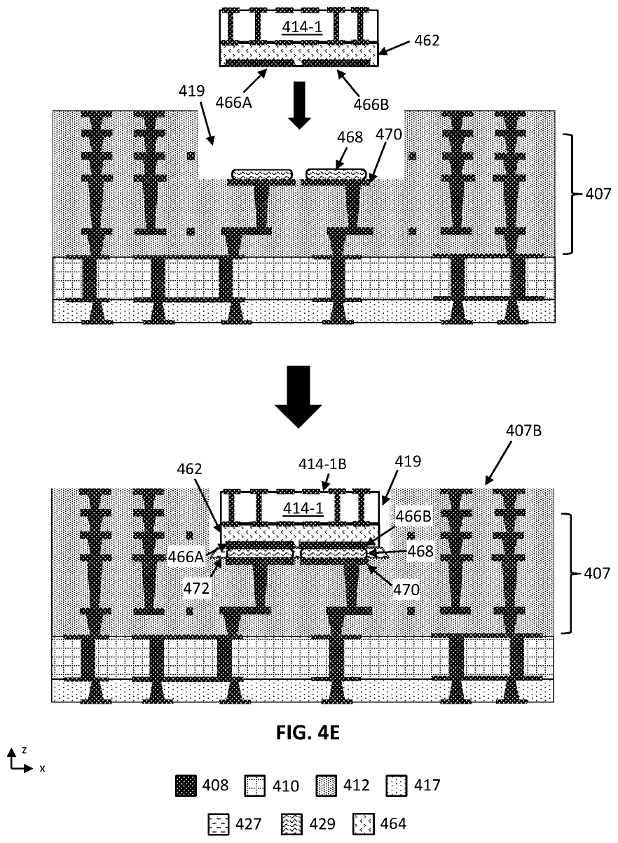

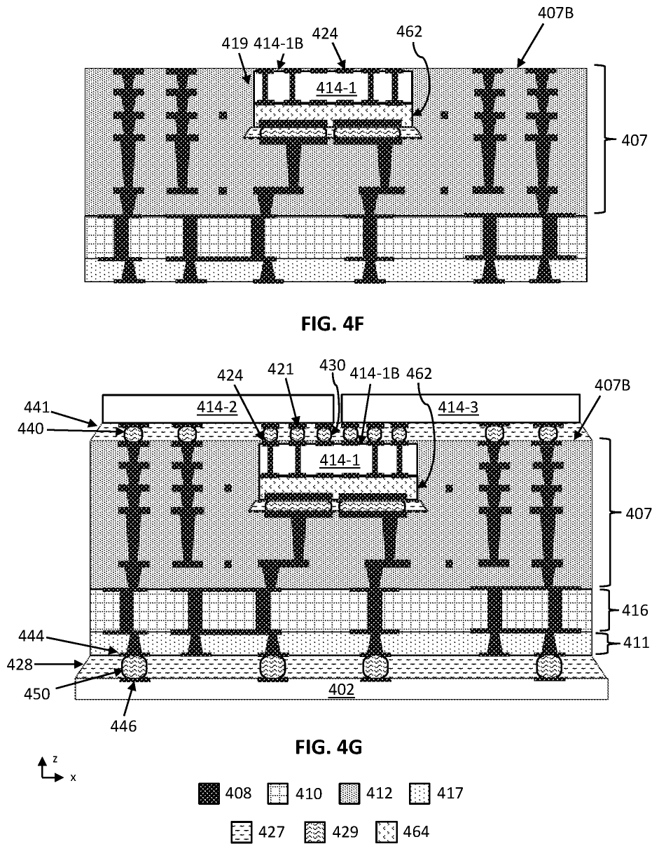

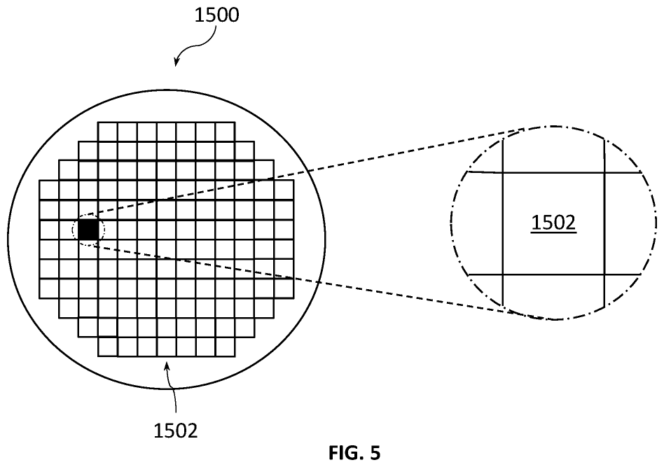

When used to describe a range of dimensions, the phrase “between X and Y” represents a range that includes X and Y. For convenience, the phrase “FIG. 1” may be used to refer to the collection of drawings of FIGS. 1A-1D, the phrase “FIG. 2” may be used to refer to the collection of drawings of FIGS. 2A-2D, the phrase “FIG. 4” may be used to refer to the collection of drawings of FIGS. 4A-4G, etc. Although certain elements may be referred to in the singular herein, such elements may include multiple sub-elements. For example, “an insulating material” may include one or more insulating materials.

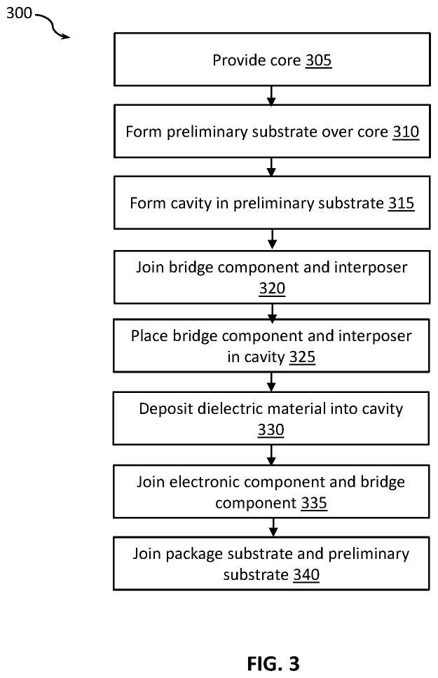

FIG. 1A is a side, cross-sectional view of an example microelectronic assembly 100, in accordance with various embodiments. The microelectronic assembly 100 may include a substrate 107 with a double-sided bridge die 114-1 that is formed within a cavity 119 in the substrate 107, as illustrated in the processes shown in FIG. 3 and FIG. 4. The substrate 107 includes a first substrate face 107A (e.g., bottom or back substrate face), and a second substrate face 107B (e.g., top or front substrate face). The substrate 107 may include a dielectric material 112 and a conductive material 108 (e.g., copper and/or another conductive material; e.g., lines/traces/pads/contacts 109A and vias 109B, as shown), with the conductive material 108 arranged in the dielectric material 112 to provide conductive pathways through the substrate 107. The bridge die 114-1 may be surrounded by the dielectric material 112 of the substrate 107.

Referring to FIG. 1B, the bridge die 114-1 may include a first bridge die face 114-1A (e.g., bottom or back bridge die face, facing the first substrate face 107A of the substrate 107). Conductive contacts 122A, 122B, 122C, 122D (collectively conductive contacts 122 or conductive features 122) may be along the first bridge die face 114-1A. The bridge die 114-1 may additionally include an opposing second bridge die face 114-1B (e.g., top or front bridge die face, facing the second substrate face 107B of the substrate 107). Conductive contacts 124A, 124B, 124C, 124D (collectively conductive contacts 124 or conductive features 124) may be along the second bridge die face 114-1B. Bridge vias 125A, 125B, 125C, 125D (collectively bridge vias 125) may couple respective conductive contacts 122, 124 (e.g., the bridge via 125A coupling conductive contact 122A and conductive contact 124A, the bridge via 125B coupling conductive contact 122B and conductive contact 124B, etc.). In some embodiments, a pitch of the conductive contacts 122 on the bridge die 114-1 may be between 10 and 500 micrometers, or between 15 and 400 micrometers, or between 20 and 300 micrometers, or between 25 and 250 micrometers, or any ranges or sub-ranges therebetween. As used herein, pitch is measured center-to-center (e.g., from a center of a conductive contact to a center of an adjacent conductive contact). In some embodiments, a pitch of the conductive contacts 124 on the bridge die 114-1 may be between 10 and 500 micrometers, or between 15 and 400 micrometers, or between 20 and 300 micrometers, or between 25 and 200 micrometers, or between 25 and 100 micrometers, or any ranges or sub-ranges therebetween. The conductive contacts 122, the conductive contacts 124, and/or the bridge vias 125 may comprise the conductive material 108 described above, or may comprise a different conductive material.

Referring back to FIG. 1A, dies 114-2, 114-3 may be present above the bridge die 114-1. The dies 114-2, 114-3 may include conductive contacts 121 along the bottom surfaces of the dies (e.g., the surfaces facing towards the second substrate face 107B of the substrate 107). The dies 114-1, 114-2, and 114-3 (collectively, dies 114) may include other conductive pathways (e.g., including lines and vias) and/or other circuitry (not shown) coupled to the respective conductive contacts (e.g., conductive contacts 121, 122, 124) on the surfaces of the dies 114. As used herein, the terms “die,” “microelectronic component,” and similar variations may be used interchangeably. As used herein, the terms “interconnect component,” “bridge die,” and similar variations may be used interchangeably. The bridge die 114-1 may be electrically coupled to dies 114-2, 114-3 by die-to-die (DTD) interconnects 130. The DTD interconnects 130 may comprise an interconnect material 129. The DTD interconnects 130 are over the second substrate face 107B of the substrate 107. In particular, conductive contacts 124 along the second bridge die face 114-1B of the bridge die 114-1 may be coupled to conductive contacts 121 on bottom surfaces of the dies 114-2, 114-3 by DTD interconnects 130.

As used herein, a “conductive contact” may refer to a portion of conductive material (e.g., metal) serving as an electrical interface between different components (e.g., part of a conductive interconnect). Conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

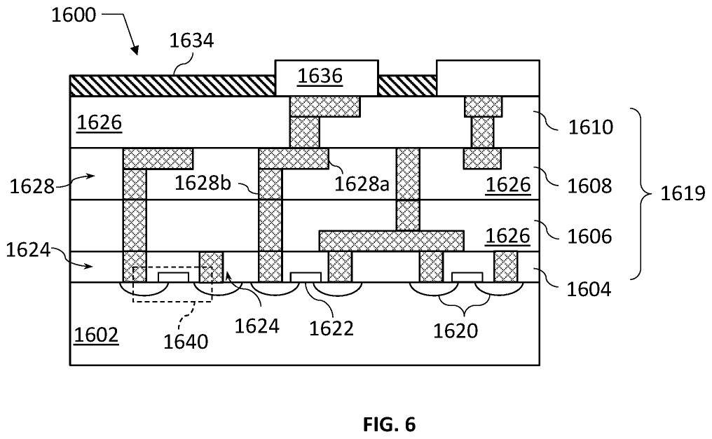

Dies 114 disclosed herein may include an insulating material (e.g., a dielectric material formed in multiple layers, as known in the art) and one or more conductive pathways formed through the insulating material. In some embodiments, the insulating material of a die 114 (e.g., any one or more of the dies 114-1, 114-2, 114-3) may include a dielectric material, such as silicon dioxide, silicon nitride, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride). The insulating material may further include one or more additional materials. For example, an insulating material may include silicon oxide or silicon nitride. The one or more conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 6. The conductive pathways in the dies 114 may be bordered by liner materials, such as adhesion liners and/or barrier liners, as suitable. In some embodiments, the die 114 (e.g., any one or more of the dies 114-1, 114-2, 114-3) is a wafer. In some embodiments, the die 114 is a monolithic silicon die, a fan-out or fan-in package die, or a die stack (e.g., wafer stacked, die stacked, or multi-layer die stacked).

In some embodiments, the die 114 may include conductive pathways to route power, ground, and/or signals to/from other dies 114 included in the microelectronic assembly 100. For example, the bridge vias 125 of the bridge die 114-1 may include a conductive material via (such as a metal via, which may be isolated from surrounding silicon or other semiconductor material by a barrier oxide), and/or the bridge die 114-1 may include other conductive pathways through which power, ground, and/or signals may be transmitted between a package substrate 102 and one or more dies 114 “above” the bridge die 114-1 (e.g., as shown in FIG. 1A, the dies 114-2 and/or 114-3). In some embodiments, the bridge die 114-1 may route power, ground, and/or signals between the dies 114-2 and/or 114-3, or from another portion of the microelectronic assembly 100 to conductive pathways in the substrate 107. In some embodiments, the bridge die 114-1 may not route power and/or ground to the dies 114-2 and 114-3; instead, the dies 114-2, 114-3 may couple to power and/or ground lines in the package substrate 102 at least in part by substrate-to-package substrate (STPS) interconnects 150, conductive material 108 (e.g., conductive pathways) in the substrate 107, and die-to-substrate (DTS) interconnects 140. The STPS interconnects 150 or the DTS interconnects 140 may comprise the same interconnect material 129 as the DTD interconnects 130, or may comprise a different interconnect material. In some embodiments, the bridge die 114-1 may be thicker than the dies 114-2, 114-3. In some embodiments, the bridge die 114-1 may be a memory device (e.g., as described below with reference to the die 1502 of FIG. 5), or a high frequency serializer and deserializer (SerDes), such as a Peripheral Component Interconnect (PCI) express. In some embodiments, the bridge die 114-1 may be a processing die, a radio frequency chip, a power converter, a network processor, a workload accelerator, a voltage regulator die, or a security encryptor. In some embodiments, the die 114-2 and/or the die 114-3 may be a processing die, a radio frequency chip, a power converter, a network processor, a workload accelerator, a voltage regulator die, or a security encryptor.

The dielectric material 112 of the substrate 107 may be formed in layers. In some embodiments, the dielectric material 112 may include an organic material, such as an organic build-up film. In some embodiments, the dielectric material 112 may include a ceramic, an epoxy film having filler particles therein, glass, an inorganic material, or combinations of organic and inorganic materials, for example. In some embodiments, the conductive material 108 may include a metal (e.g., copper). In some embodiments, the substrate 107 may include layers of dielectric material 112/conductive material 108, with lines/traces/pads/contacts 109A of conductive material 108 in one layer electrically coupled to lines/traces/pads/contacts 109A of conductive material 108 in an adjacent layer by vias (e.g., vias 109B) of conductive material 108 extending through the dielectric material 112. Conductive lines/traces/pads/contacts 109A may be referred to herein as “conductive lines,” “conductive traces,” “conductive pads,” or “conductive contacts.” A substrate 107 including such layers may be formed using a printed circuit board (PCB) fabrication technique, for example.

An individual layer of dielectric material 112 may include a cavity 119 and the bridge die 114-1 may be at least partially nested or partially embedded in the cavity 119. The bridge die 114-1 may be surrounded by (e.g., embedded in, encased in, or enclosed in) a next individual layer or mass of dielectric material 112. In some embodiments, the cavity 119 is tapered, narrowing towards a bottom surface of the cavity 119. In some embodiments, the bridge die 114-1 is partially nested in a cavity 119, and a top surface of the bridge die 114-1 may extend above a top surface of the dielectric material 112. In some embodiments, the bridge die 114-1 is fully nested in a cavity 119, and a top surface of the bridge die 114-1 may be planar with a top surface of the dielectric material 112, or may be below a top surface of the dielectric material 112.

The substrate 107 may include N layers of conductive material 108, where N is an integer greater than or equal to one; in the accompanying drawings, the layers are labeled in descending order from the second substrate face 107B of the substrate 107 (e.g., layer N, layer N-1, layer N-2, etc.). In particular, as shown in FIG. 1, a substrate 107 may include five metal layers (e.g., N, N-1, N-2, N-3, N-4, and N-5). The N metal layer may include conductive contacts 109A at a top surface of the substrate 107 that are coupled to conductive contacts 121 at bottom surfaces of the dies 114-2, 114-3 by DTS interconnects 140. The N-3 metal layer, for example, may include conductive traces 109A having a top surface, an opposing bottom surface, and lateral surfaces extending between the top and bottom surfaces of the conductive traces 109A.

Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. Further, although a particular number of layers of dielectric material 112/conductive material 108 are shown in the substrate 107, these layers may represent only a portion of the substrate 107, for example, fewer layers may be present, or further layers may be present (e.g., layers N-6, N-7, etc., of conductive material 108). As shown in FIG. 1, the substrate 107 may further include a core 116 with through core vias 115 and one or more further layers 111 including a further layer material 117 (e.g., a dielectric material, an adhesive material, etc.) may be present below the core 116. The substrate 107 (e.g., the lower layer(s) 111) may be coupled to a package substrate 102 by STPS interconnects 150. The core 116 may include a core material 110, which may include any suitable material, including glass, a fiber-reinforced epoxy, an organic dielectric material, such as an epoxy, or a phenolic resin or polyimide resin reinforced with glass, aramid, or nylon. In some embodiments, a substrate 107 may not include a core 116 and/or further layers 111.

The microelectronic assembly 100 may include an interposer 162. The interposer 162 may be in the cavity 119 of the substrate 107 and under the bridge die 114-1 (i.e., the bridge die 114-1 may be over the interposer 162). Referring to the area 160 of FIG. 1B (e.g., outlined with a dotted line in FIG. 1A), the interposer 162 may include a first (e.g., bottom or back) interposer face 162A (e.g., facing the first substrate face 107A) and a second (e.g., top or front) interposer face 162B opposite the first interposer face 162A (e.g., facing the first bridge die face 114-1A and the second substrate face 107B).

The interposer 162 may include an interposer material 164. The interposer material 164 may be selected depending on the design requirements of the microelectronic assembly 100 in which the interposer 162 is used. The selection of interposer material 164 may be based at least in part on material properties of the bridge die 114-1 and/or substrate 107, input and/or output voltages of one or more electrical current flows passing through the interposer 162, or other factors, as described further below.

In some embodiments, the interposer material 164 may be or include a glass material, and the interposer 162 may be or include a glass structure. As used herein, the term “glass structure” refers to a layer (e.g., a glass layer) or a structure (e.g., a portion of a glass layer or another article) of any glass material such as quartz, silica, fused silica, silicate glass (e.g., borosilicate, aluminosilicate, aluminoborosilicate, alkali borosilicate, alkali aluminosilicate, alkali aluminoborosilicate, etc.), soda-lime glass, soda-lime silica, borofloat glass, fusion draw glass, chemically strengthened glass (e.g., by ion exchange treatment), lead borate glass, photosensitive glass, non-photosensitive glass, or ceramic glass. In particular, the glass structure may be bulk glass or a solid volume/layer of glass, as opposed to, e.g., materials that may include particles of glass, such as glass fiber-reinforced polymers (e.g., as may be used for substrates/boards constructed of glass fibers and an epoxy binder). Such glass materials are typically non-crystalline, often transparent, amorphous solids. In some embodiments, the glass structure may be an amorphous solid glass layer. In some embodiments, the glass structure may include a material comprising silicon and oxygen, as well as any one or more of aluminum, boron, magnesium, calcium, barium, tin, sodium, potassium, strontium, phosphorus, zirconium, lithium, titanium, and zinc. In some embodiments, the glass structure may include a material, e.g., any of the materials described above, with a weight percentage of silicon being at least about 0.5%, e.g., between about 0.5% and about 50%, between about 1% and about 48%, at least about 23%, or any ranges or sub-ranges therebetween. For example, if the glass structure is fused silica, the weight percentage of silicon may be about 47%. In some embodiments, the glass structure may include a material having at least about 23% silicon and/or at least about 26% oxygen by weight, and, in some further embodiments, the glass structure may further include at least about 5% aluminum by weight. In some embodiments, the glass structure may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass structure may be a layer of glass that does not include an organic adhesive or an organic material. The glass structure or glass material may have a coefficient of thermal expansion (CTE) that is similar to or compatible with other components of the microelectronic assembly 100, including the bridge die 114-1, potentially allowing for reduced stresses, strains, and/or warp resulting from thermal cycling. The glass material may also provide structural rigidity to the substrate 107, which may help prevent fracture or cracking of the substrate 107 or other components of the microelectronic assembly 100 due to stresses, strains, and/or warp.

In some embodiments, the interposer material 164 may include a semiconductor material. In some embodiments, the semiconductor material may include Si. Use of Si as an interposer material 164 may be suitable for applications in which electricity of a moderate voltage (e.g., 3V or 3.3V) is to be relayed along conductive features in the interposer 162, and can allow for the interposer 162 to efficiently be fabricated using conventional Si processing or fabrication technologies at a high throughput or yield.

In some embodiments, the semiconductor material may include one or more of silicon, gallium, nitrogen, and carbon, and/or another material. The semiconductor material may be a wide bandgap material (e.g., having a bandgap greater than that of Si). For example, the semiconductor material may include gallium and nitrogen (such as GaN), or the semiconductor material may include silicon and carbon (such as SiC). An interposer 162 including a wide bandgap material such as GaN or SiC as an interposer material 164 may be suitable for receiving or channeling electricity (e.g., power) of a high voltage (e.g., 5V, or greater than 5V) along conductive features in the interposer 162. In some cases, such an interposer material 164 may be used for high-temperature applications (e.g., higher than an operating temperature suitable for Si; depending on various factors, including suitable operational temperatures of, and materials used for, other components of the microelectronic assembly 100, such as the bridge die 114-1 and/or dies 114-2, 114-3).

In some embodiments, multiple materials may be used. For example, the interposer 162 may include glass (potentially having a favorable CTE or rigidity) or Si (potentially having favorable manufacturability, e.g. high manufacturing throughput or yield), and may also include conductive features comprising a wide bandgap material such as GaN or SiC (potentially suitable for receiving or channeling electricity of a high voltage).

In some embodiments, the interposer material 164 may include a non-glass inorganic material (e.g., sapphire or another non-glass inorganic material) or an organic material.

In some embodiments, the interposer 162 may be a monolithic structure. In some embodiments, the interposer 162 may be formed from multiple structures, or may be formed in layers. In some embodiments, the multiple structures or layers of the interposer 162 may be formed from the same material, or from different materials (e.g., organic and inorganic materials, glass and a semiconductor material, etc.). In some embodiments, multiple interposers (e.g., stacked or side-by-side) may be included. If multiple interposers are included, one or more intermediate layers or structures may be in between the multiple interposers.

Although the bridge die 114-1 and the interposer 162 are shown in FIG. 1B as having a similar dimension (e.g., a length) along the x-axis, in some embodiments, the bridge die 114-1 and the interposer 162 may differ in one or more dimensions. For example, the bridge die 114-1 and the interposer 162 may differ in a length and/or a width (e.g., along x- and/or y-axes). The bridge die 114-1 and the interposer 162 may differ in a height (e.g., along the z-axis in FIG. 1B).

Although FIG. 1B shows one bridge die 114-1 and one interposer 162 in one cavity 119, in some embodiments, multiple bridge dies 114-1 and/or multiple interposers 162 may be in the cavity 119. In some embodiments, multiple bridge dies 114-1 may be over a single interposer 162. For example, multiple ones of the bridge die 114-1, or multiple different bridge dies, may be positioned side-by-side (possibly with one or more intermediate layers or structures therebetween). As another example, multiple interposers 162 may be under one bridge die 114-1 (e.g., two or more of the interposer 162 may be positioned side-by-side under a single bridge die 114-1, possibly with one or more intermediate layers or structures therebetween). In some embodiments, a substrate 107 may include multiple cavities 119, and one or more bridge dies 114-1 and/or one or more interposers 162 may be in each cavity 119.

The interposer 162 may include a conductive material 108 that is the same as or similar to the conductive material 108 included in the substrate 107. For example, as shown in FIG. 1C, the conductive material 108 in the interposer 162 may include lines/traces/pads/contacts 163A (e.g., extending in the interposer material 164 along the x-axis in FIG. 1C) and vias 163B (e.g., extending in the interposer material 164 along the z-axis in FIG. 1C). The interposer 162 may include L layers of conductive material 108, wherein L is an integer greater than or equal to one. In FIG. 1C, the L layers (three metal layers in the example shown in FIG. 1C) are labeled in descending order from the second interposer face 162B of the interposer 162 (e.g., L, L-1, L-2). The conductive contacts 122 may be along the L metal layer. Although a particular number and arrangement of layers of conductive material 108 in the interposer 162 are shown in FIG. 1C, the particular number and arrangement are simply illustrative, and any desired number of conductive layers or arrangement of conductive material 108 may be used in the interposer 162. Further, although a particular number of layers of conductive material 108 are shown in the interposer 162, these layers may represent only a portion of the interposer 162. In some embodiments, for example, fewer layers may be present, or further layers may be present (e.g., layers L-3, L-4, etc., of conductive material 108).

The conductive material 108 in the interposer 162 can couple conductive contacts (e.g., conductive contacts 166A, 166B, or collectively conductive contacts 166 or conductive features 166) along the first interposer face 162A (e.g., the bottom or back side of the interposer, facing the substrate 107) to conductive contacts (e.g., conductive contacts 122A, 122B, 122C, 122D, or collectively conductive contacts 122 or conductive features 122) along the second interposer face 162B (e.g., the top or front side of the interposer, facing the bridge die 114-1). As shown in the x-z plane cross-section of FIG. 1C, conductive material 108 in the interposer 162 couples the conductive contact 122C and the conductive contact 166A. In another x-z plane cross-section, for example, conductive material 108 in the interposer 162 may couple the conductive contact 122B and the conductive contact 166B. Other couplings of conductive contacts 166 and conductive contacts 122 via the conductive material 108 in the interposer 162 are possible.

The conductive material 108 in the interposer 162 may allow for electricity (e.g., power or current) to travel through the interposer 162. Electricity may travel upwards in the z-direction as shown in FIG. 1B. For example, electricity may travel from conductive material 108 in the substrate 107 (e.g., vias 109B and conductive contacts 170) to conductive contacts 166 along the first interposer face 162A via interposer-to-substrate (ITS) interconnects 168. Electricity may travel between conductive contacts 166 along the first interposer face 162A and conductive contacts 122 along the second interposer face 162B via conductive material 108 in the interposer 162 (e.g., via lines/traces/pads/contacts 163A and vias 163B in the interposer 162 as shown in FIG. 1C). Electricity may travel between conductive contacts 122 along the second interposer face 162B and first bridge die face 114-1A and conductive contacts 124 along the second bridge die face 114-1B by bridge vias 125. Electricity may travel from the conductive contacts 124 along the second bridge die face 114-1B to conductive contacts 121 along the bottom surfaces of dies 114-2, 114-3 via DTD interconnects 130, or elsewhere in the microelectronic assembly 100. Similarly, electricity may travel downwards in the z-direction as shown in FIG. 1B along the same or similar components as described above (e.g., from conductive contacts 121 to conductive contacts 124 via DTD interconnects 130, from conductive contacts 124 to conductive contacts 122 via bridge vias 125, etc.).

The conductive material 108 in the interposer 162 (including lines/traces/pads/contacts 163A and vias 163B) may serve as a redistribution layer, coupling conductive contacts 166 and conductive contacts 122 to provide particular voltages at different pads of the bridge die 114-1 and, in some cases, to the dies 114-2 and 114-3 coupled to the bridge die 114-1. For example, in FIG. 1C, conductive material 108 in the interposer 162 (e.g., line 163A and vias 163B) may be used to channel electrical current flow at a given voltage between conductive contact 166A and conductive contact 122C. In another x-z plane cross-section, for example, conductive material 108 in the interposer 162 may be used to channel electrical current flow at a given voltage between conductive contact 166B and conductive contact 122B. Through the redistribution layer (e.g., the conductive material 108 in the interposer 162), corresponding conductive features (such as the conductive contact 166A and the conductive contact 122C, or the conductive contact 166B and the conductive contact 122B) may be joined even if the corresponding conductive features are not directly aligned along opposed faces of the interposer (e.g., the first interposer face 162A and the second interposer face 162B), allowing for design flexibility.

The interposer 162 may include a PMIC, power management circuitry, or another feature with power management functionality. In some embodiments, and as noted above, the power management circuitry may include voltage regulation circuitry. For example, in some embodiments, electrical current flow of a first voltage (i.e., an input voltage of 0.8V, 1.8V, 3.3V, 5V, or 12V, for example) passing through a conductive contact or feature along the first interposer face 162A (e.g., conductive feature 166A) may be stepped down to a second, lower voltage, referred to as an output voltage, before the electrical current flow moves to a conductive contact or feature along the second interposer face 162B (e.g., conductive feature 122C) along the conductive material 108 in the interposer 162. The voltage stepped-down electrical current flow may be channeled to an electronic device in the microelectronic assembly 100 (e.g., to the bridge die 114-1, and/or to the dies 114-2 and/or 114-3). For voltage step-down, the interposer 162 may include a step-down converter (e.g., a buck converter or chopper, a DC-DC converter such as a linear or switching DC-DC converter/regulator, etc.). In some embodiments, the interposer 162 may include another feature with power management functionality (e.g., an isolated or non-isolated DC-DC converter, a step-up or DC-DC boost converter, a universal DC-to-DC converter, an inverting DC-to-DC converter, a load switch, an AC-to-DC converter, a driver, a battery charger, etc.). Components of the power management circuitry or voltage regulation circuitry may include a capacitor, an inductor, a resistor, or another component, as described further later in this disclosure. Including power management circuitry or voltage regulation circuitry in the interposer 162 can allow power management functions (for example, voltage step-down) to be performed on electrical current flows (e.g., power) to electronic devices as noted above. The proximity of the interposer 162 including power management circuitry or voltage regulation circuitry to the electronic device can lead to reduced power loss and reduced generation of waste heat.

For example, in some embodiments, the conductive contact 166A may correspond to electrical current flow of a first voltage, the conductive contact 122C may correspond to electrical current flow of a second voltage, and the conductive material 108 (for example, a part of a redistribution layer) may couple the conductive contacts 166A, 122C. In some embodiments, the first voltage and the second voltage may be different voltages, and an electrical current flow between the conductive contact 166A and the conductive contact 122C may be voltage-regulated by voltage regulation circuitry (e.g., the voltage regulation circuitry described above) within the interposer 162. For example, the first voltage may be stepped down to a second, lower voltage by a step-down converter of the interposer 162.

Referring to FIG. 1C, the conductive contacts 166 (e.g., first set of conductive features 166, or first set of electrical connections 166) and the conductive contacts 122 (e.g., second set of conductive features 122, or second set of electrical connections 122) include different numbers of conductive features. In particular, a smaller number of conductive features is included in the first set of conductive features 166 than in the second set of conductive features 122. For example, the first set of conductive features 166 may include four conductive features (e.g., the two conductive features 166A, 166B in the cross-section shown in FIG. 1C, and two other conductive features in one or more different cross-sections), and the second set of conductive features 122 may include sixteen conductive features (e.g., the four conductive features 122A, 122B, 122C, 122D in the cross-section shown in FIG. 1C, and twelve other conductive features in one or more different cross-sections). Including a smaller number of conductive features in the first set of conductive features 166 than the number of conductive features in the second set of conductive features 122 may reduce error or mismatch during alignment and bonding or joining of the first set of conductive features 166 and conductive material 108 in the substrate 107 (e.g., corresponding conductive contacts 170 in the substrate 107, via ITS interconnects 168). For example, having a smaller number of conductive features in the first set of conductive features 166 may permit at least some of the first set of conductive features 166 to be larger (e.g., longer in an x-axis direction of the coordinate system shown, or longer in both the x-axis and y-axis directions (e.g., the y-axis direction extending into the page in FIG. 1C)), i.e., having an overall larger footprint. Larger conductive features for the first set of conductive features 166 can potentially increase an alignment tolerance (e.g., acceptable deviations in position) between the first set of conductive features 166 and corresponding conductive contacts 170 (e.g., the relative positions of the conductive features in the first set of conductive features 166 and the corresponding conductive contacts 170 can deviate from the positions required for an ‘ideal’ alignment when bonding or joining).

Although particular numbers and arrangements of conductive features in the first set of conductive features 166 and in the second set of conductive features 122 are described, the particular numbers and arrangements are simply illustrative, and other numbers of conductive features in the first set of conductive features 166 and in the second set of conductive features 122 may be included. Conductive features in the first set of conductive features 166 and in the second set of conductive features 122 may correspond to ground or non-ground voltages. For example, in some embodiments, the first set of conductive features 166 may include two conductive features corresponding to different voltages (e.g., a high voltage and a ground voltage) and the second set of conductive features 122 may include three conductive features corresponding to different voltages (e.g., a high voltage, a low voltage, and a ground voltage). As another example, in some embodiments, the first set of conductive features 166 may include four conductive features corresponding to different voltages (e.g., a high voltage, a ground voltage, and two voltages in between the high voltage and the ground voltage or under the ground voltage) and the second set of conductive features 122 may include six conductive features corresponding to different voltages (e.g., a high voltage, a ground voltage, and four voltages in between the high voltage and the ground voltage or under the ground voltage). In some embodiments, more than one conductive feature in the first set of conductive features 166 may correspond to a given voltage. In some embodiments, more than one conductive feature in the second set of conductive features 122 may correspond to a given voltage.

As noted above, the first set of conductive features 166 and the second set of conductive features 122 may correspond to different voltages. Voltage regulation circuitry in the interposer 162 may be used to convert voltages of electrical current flows passing through the first set of conductive features 166 to voltages suitable for one or more electronic components (e.g., one or more of the dies 114). Conductive features of the first set of conductive features 166 (e.g., 166A, 166B) may correspond to a first set of voltages (e.g., 166A to 1.8V, 166B to ground/0V), and conductive features of the second set of conductive features 122 may correspond to a second set of voltages (e.g., 122A to ground/0V, 122B to 1.3V, 122C to 1.8V, 122D to 0.8V). In this example, the second set of voltages includes a greater number of voltages (e.g., four voltages) than the number of voltages in the first set of voltages (e.g., two voltages). Voltage regulation circuitry in the interposer 162 may be used to step-down voltages of electrical current flow between the first set of conductive features 166 and the second set of conductive features 122 as desired for a given set of design requirements (e.g., including power requirements for electronic devices in the microelectronic assembly 100). For example, in the cross-section shown in FIG. 1C, the conductive features 166A and 122C are joined (e.g., by conductive material 108 in the interposer 162). Both conductive features 166A, 122C may correspond to 1.8V, and no voltage step-down may be required for electrical current flow passing therebetween. In another x-z cross-section (e.g., parallel to the cross-section shown in FIG. 1C), conductive features 166A and 122B may be joined, and voltage regulation circuitry in the interposer 162 may be used to step down electrical current flow passing therebetween (e.g., from 1.8V at conductive feature 166A to 1.3V at conductive feature 122B). Similarly, in another x-z cross-section, conductive features 166A and 122D may be joined, and voltage regulation circuitry in the interposer 162 may be used to step down electrical current flow passing therebetween (e.g., from 1.8V at conductive feature 166A to 0.8V at conductive feature 122D). Other conductive features of the microelectronic assembly 100 (e.g., the bridge vias 125A, 125B, 125C, 125D, the conductive contacts 124A, 124B, 124C, 124D, etc.) may also correspond to various voltages and may be joined with the conductive contacts 122 to permit electrical power flows of desired voltages to be passed to electronic components in the microelectronic assembly 100.

In some embodiments, the number of voltages in the second set of voltages corresponding to the second set of conductive features 122 may be equal to the number of conductive features in the first set of conductive features 166. As an example, the first set of conductive features 166 may correspond to a first set of voltages (e.g., 166A to 3.0V, 166B to ground/0V), and the second set of conductive features 122 may correspond to a second set of voltages (e.g., 122A to ground/0V, and 122B, 122C, and 122D to 3.0V). The conductive feature 166A may be joined to conductive features 122B, 122C, and 122D (e.g., along the cross-section shown in FIG. 1C, and in different cross-sections), e.g. by a redistribution layer of conductive material 108 in the interposer 162.

Referring back to FIG. 1B, the interposer 162 may be joined or coupled to the bridge die 114-1. In particular, the second interposer face 162B may be coupled to the first bridge die face 114-1A, with the conductive contacts 122 along the second interposer face 162B (e.g., electrical connections between the second interposer face 162B and the first bridge die face 114-1A, described in further detail later in this specification). The bridge die 114-1 and interposer 162 may be bonded (e.g., at the conductive contacts 122) using any suitable technique, including direct bonding, hybrid bonding, solder bonding, bump bonding, and so on, as described in further detail later in this specification. In some embodiments, one or more intermediary layers (not shown; e.g., an adhesive, a dielectric layer, an underfill layer, or one or more other layers or materials) may be in between the interposer 162 and the bridge die 114-1. The bridge vias 125 may extend through the one or more intermediary layers such that the conductive contacts 122 lie along the second interposer face 162B. The conductive contacts 166 along the first interposer face 162A may be coupled to conductive contacts 170 in the substrate 107 (e.g., in the cavity 119 in the substrate 107) by ITS interconnects 168. The ITS interconnects 168 may include an interconnect material that is the same as or similar to the interconnect material 129 of the DTD interconnects 130. An underfill layer 172 comprising an underfill material 127 may extend between the first interposer face 162A and the substrate 107 (e.g., a bottom of the cavity 119 in the substrate 107) around the ITS interconnects 168. The use of ITS interconnects 168 as described to couple conductive contacts 166 and conductive contacts 170 is simply an example, and other methods may be used to join the conductive contacts 166 and conductive contacts 170 (for example, direct bonding or hybrid bonding, as described later in this specification). In some embodiments, the ITS interconnects 168 and/or underfill layer 172 may not be present.

In some embodiments, a width or a length of a conductive feature in the first set of conductive features 166 may be greater than a width or a length of a conductive feature in the second set of conductive features 122. Referring to FIG. 1D, a top-down or plan view of a conductive feature 166A of the first set of conductive features 166 is shown next to a top-down or plan view of a conductive feature 122A of the second set of conductive features 122. The conductive feature 166A includes a first side 174 having a width 175 and a second side 176 having a length 177. The conductive feature 122A includes a first side 184 having a width 185 and a second side 186 having a length 187. The width 175 of the first side 174 of the conductive feature 166A may be greater than the width 185 of the first side 184 of the conductive feature 122A. The length 177 of the second side 176 of the conductive feature 166A may be greater than the length 187 of the second side 186 of the conductive feature 122A. In some embodiments, a cross-sectional area of the conductive feature 166A (e.g., the width 175 multiplied by the length 177) may be greater than a cross-sectional area of the conductive feature 122A (e.g., the width 185 multiplied by the length 187). Including conductive features of a greater size (e.g., having a greater width, length, cross-sectional area, or footprint) in the first set of conductive features 166 than a size of conductive features in the second set of conductive features 122 may allow for reduced error or mismatch during alignment (e.g., increased alignment tolerance) and bonding or joining between the first set of conductive features 166 and conductive material 108 in the substrate 107 (e.g., corresponding conductive contacts 170 in the substrate 107, via ITS interconnects 168). Although relative sizes and shapes of conductive features in the first set of conductive features 166 and in the second set of conductive features 122 are shown, the particular sizes and shapes are simply illustrative, and other sizes or shapes in the first set of conductive features 166 and in the second set of conductive features 122 may be used. For example, in some embodiments, the first set of conductive features 166 and the set of conductive features 122 may include conductive features having a rectangular, ellipse, or circular cross-section.

The microelectronic assembly 100 of FIG. 1 may also include an underfill layer 128 comprising an underfill material 127. In some embodiments, the underfill layer 128 may extend between the substrate 107 and the package substrate 102 around the associated STPS interconnects 150. In particular, the underfill layer 128 may extend between the core 116 and/or further layers 111 and the package substrate 102 around the associated STPS interconnects 150. In some embodiments, an underfill layer 141 (e.g., comprising the same underfill material 127 and/or a different underfill material) may extend between the dies 114-2, 114-3 (e.g., top level dies) and the top surface of the substrate 107 around the associated DTS interconnects 140 and/or between the bridge die 114-1 and the top level dies 114-2, 114-3 around the associated DTD interconnects 130. As noted above, in some embodiments, the underfill layer 172 (e.g., comprising the same underfill material 127 or a different underfill material) may extend between the interposer 162 and the substrate 107 around the ITS interconnects 168. The underfill material 127 may include an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the conductive contacts 144 to the conductive contacts 146 of the package substrate 102 when forming the STPS interconnects 150, and then polymerizes and encapsulates the STPS interconnects 150. The underfill material 127 may be selected to have a CTE that may mitigate or minimize the stress between the substrate 107 and the package substrate 102 (or between the core 116/further layers 111 and the package substrate 102) arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the dies 114 and/or dielectric material 112 of the substrate 107.

The STPS interconnects 150 disclosed herein may take any suitable form. The STPS interconnects 150 may comprise the same interconnect material 129 as the DTD interconnects 130, and/or may comprise a different interconnect material. In some embodiments, a set of STPS interconnects 150 may include solder (e.g., solder bumps or balls that are subject to a thermal reflow to form the STPS interconnects 150). For example, as shown in FIG. 1, the STPS interconnects 150 may include solder between the conductive contact 144 and the conductive contact 146 on the top surface of the package substrate 102. In some embodiments, a set of STPS interconnects 150 may include an anisotropic conductive material, such as an anisotropic conductive film or an anisotropic conductive paste. An anisotropic conductive material may include conductive materials dispersed in a non-conductive material.

Similarly, the ITS interconnects 168 disclosed herein may take any suitable form. The ITS interconnects 168 may comprise the same interconnect material 129 as the DTD interconnects 130 or the STPS interconnects 150, and/or may comprise a different interconnect material. In some embodiments, a set of ITS interconnects 168 may include solder (e.g., solder bumps or balls that are subject to a thermal reflow to form the ITS interconnects 168). For example, as shown in FIG. 1, the ITS interconnects 168 may include solder between conductive contacts 166 on the bottom surface of the bridge die 114-1 and conductive contacts 170 in the substrate 107. In some embodiments, a set of ITS interconnects 168 may include an anisotropic conductive material, such as an anisotropic conductive film or an anisotropic conductive paste. An anisotropic conductive material may include conductive materials dispersed in a non-conductive material.

The DTD interconnects 130 disclosed herein may take any suitable form. As noted earlier, the DTD interconnects 130 may comprise a interconnect material 129. The DTD interconnects 130 may have a finer pitch than the STPS interconnects 150 in the microelectronic assembly 100. In some embodiments, the dies 114 on either side of a set of DTD interconnects 130 may be unpackaged dies, and/or the DTD interconnects 130 may include small conductive bumps (e.g., copper bumps). The DTD interconnects 130 may have too fine a pitch to couple to the package substrate 102 directly (e.g., too fine to serve as DTS interconnects 140 or STPS interconnects 150). In some embodiments, a set of DTD interconnects 130 may include solder. In some embodiments, a set of DTD interconnects 130 may include an anisotropic conductive material. In some embodiments, a set of DTD interconnects 130 may include any of the materials discussed above for the ITS interconnects 168, the STPS interconnects 150, or the DTS interconnects 140. In some embodiments, the DTD interconnects 130 may be used for data transfer lines, while the STPS interconnects 150 may be used for power and ground lines, among others. In some embodiments, some or all of the DTD interconnects 130 in the microelectronic assembly 100 may be metal-to-metal interconnects (e.g., copper-to-copper interconnects, or plated interconnects). In such embodiments, the DTD interconnect 130 may be bonded (e.g., to vias 109B and conductive contacts 121 on the bottom surfaces of dies 114-2, 114-3) under elevated pressure and/or temperature, without the use of intervening solder or an anisotropic conductive material. Any of the conductive contacts disclosed herein (e.g., the conductive contacts 121, 124, 144, and/or 146) may include bond pads, solder bumps, conductive posts, or any other suitable conductive contact, for example. In some embodiments, some or all of the DTD interconnects 130, the DTS interconnects 140, and/or the ITS interconnects 168 in a microelectronic assembly 100 may be solder interconnects that include a solder with a higher melting point than a solder included in some or all of the STPS interconnects 150. For example, when the DTD interconnects 130, the DTS interconnects 140, and the ITS interconnects 168 in a microelectronic assembly 100 are formed before the STPS interconnects 150 are formed, solder-based DTD interconnects 130, DTS interconnects 140, and ITS interconnects 168 may use a higher-temperature solder (e.g., with a melting point above 200 degrees Celsius), while the STPS interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In the microelectronic assemblies 100 disclosed herein, some or all of the DTS interconnects 140 and the STPS interconnects 150 may have a larger pitch than some or all of the DTD interconnects 130. DTD interconnects 130 may have a smaller pitch than STPS interconnects 150 or the DTS interconnects 140 due to the greater similarity of materials in the different dies 114 on either side of a set of DTD interconnects 130 than between the substrate 107 and the top level dies 114-2, 114-3 on either side of a set of DTS interconnects 140, and between the substrate 107 and the package substrate 102 on either side of a set of STPS interconnects 150. In particular, the differences in the material composition of a substrate 107 and a die 114 or a package substrate 102 may result in differential expansion and contraction due to heat generated during operation (as well as the heat applied during various manufacturing operations). To mitigate damage caused by this differential expansion and contraction (e.g., cracking, solder bridging, etc.), the DTS interconnects 140 and the STPS interconnects 150 may be formed larger and farther apart than DTD interconnects 130, which may experience less thermal stress due to the greater material similarity of the pair of dies 114 on either side of the DTD interconnects 130. In some embodiments, the DTS interconnects 140 disclosed herein may have a pitch between 25 micrometers and 250 micrometers, or any ranges or sub-ranges therebetween. In some embodiments, the STPS interconnects 150 disclosed herein may have a pitch between 55 micrometers and 1000 micrometers, or any ranges or sub-ranges therebetween, while the DTD interconnects 130 disclosed herein may have a pitch between 25 micrometers and 100 micrometers, or any ranges or sub-ranges therebetween.

The microelectronic assembly 100 of FIG. 1 may also include a circuit board (not shown). The package substrate 102 may be coupled to the circuit board by second-level interconnects at the bottom surface of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the substrate 107 may not be coupled to a package substrate 102 (e.g., through the STPS interconnects 150), but may instead be coupled to a circuit board, such as a PCB.

Although FIG. 1 depicts a microelectronic assembly 100 having a particular number of dies 114 and conductive material 108 (e.g., conductive pathways) coupled to other dies 114, this number and arrangement are simply illustrative, and a microelectronic assembly 100 may include any desired number and arrangement of dies 114. Although FIG. 1 shows the bridge die 114-1 as a double-sided die and the dies 114-2, 114-3 as single-sided dies, the dies 114-2, 114-3 may be double-sided dies. The dies 114 may be single-pitch dies or mixed-pitch dies. In some embodiments, additional components may be disposed on the top surfaces of the dies 114-2 and/or 114-3. In this context, a double-sided die refers to a die that has connections on both surfaces. In some embodiments, a double-sided die may include vias (e.g., through silicon vias or TSVs) to form connections on both surfaces. An active surface of a double-sided die, which is a surface containing one or more active devices and a majority of interconnects, if present, may face any direction depending on the design and electrical requirements.

Many of the elements of the microelectronic assembly 100 of FIG. 1 are included in other ones of the accompanying drawings; the discussion of these elements is not repeated when discussing these drawings, and any of these elements may take any of the forms disclosed herein. Further, a number of elements are illustrated in FIG. 1 as included in the microelectronic assembly 100, but a number of these elements may not be present in a microelectronic assembly 100. For example, in various embodiments, the further layers 111, the underfill layers 128, 141, and/or 172, and/or the package substrate 102 may not be included. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

As described above, the interposer 162 may include power management circuitry (e.g., voltage regulation circuitry). The power management circuitry of the interposer 162 may include an electrical component (for example, a capacitor, an inductor, a resistor, etc.). FIGS. 2A-2D are side, cross-sectional views of example interposers including electrical components.

FIG. 2A illustrates a cross-section of an interposer 210 having an electrical component 212 embedded in the interposer 210. The electrical component 212 may be separately fabricated and packaged prior to integration in the interposer 210. The electrical component 212 may include one or more passive components or another electrical component. The electrical component 212 may include a power management circuitry component. The electrical component 212 may include one or more passive devices of the same or different types, e.g., one or more inductors, one or more capacitors, one or more resistors, etc. The electrical component 212 may be in a package that is attached to the interposer 210 (e.g., embedded in a cavity or recess of the interposer 210). While the electrical component 212 in FIG. 2A is illustrated as being near an upper face of the interposer 210, in other embodiments, the electrical component 212 may be in a central portion of the interposer 210, or may be near a bottom of the interposer 210 (e.g., in a recess along a base or bottom of the interposer 210). In still other embodiments, the electrical component 212 may be attached to a top or bottom surface of the interposer 210.

In this example, conductive material 208 is coupled to the electrical component 212, and the conductive material 208 may couple the electrical component 212 to a conductive contact 266 (which may be the same as or similar to one of the first conductive contacts 166 shown in FIG. 1C) and a conductive contact 222 (which may be the same as or similar to one of the second conductive contacts 122 shown in FIG. 1C), where the conductive contact 222 may be along a surface of a bridge die (e.g., the first bridge die face 114-1A of the bridge die 114-1 shown in FIG. 1B). In some embodiments, more or fewer conductive contacts 222, 266 and/or more or less conductive material 208 may be included (e.g., based on the number and arrangement of conductive contacts 222, 266 or electrical components 212, or based on design specifications (e.g., power or voltage delivery specifications) of a microelectronic assembly 100 including the interposer 210).

FIG. 2B illustrates a cross-section of an interposer 220 having conductive material 208 therein that is arranged to form an electrical component, and in particular, an inductor 223, which may be coupled to a conductive contact 266 and a conductive contact 222. The conductive contact 266 and the conductive contact 222 may be the same as described for FIG. 2A above. FIG. 2C is a cross-section through the plane AA′ in FIG. 2B. In this example, the inductor 223 is formed from a coil of conductive material 208. In some embodiments, the inductor 223 has a different shape. In some embodiments, multiple electrical components (e.g., multiple inductors) are formed in the interposer 220.

The inductor 223 may be formed by etching a portion of the interposer 220 and filling the etched portion with the conductive material 208. In some embodiments, the conductive material 208 of the inductor 223 may be deposited after the interposer 220 has been mounted to a substrate (e.g., the substrate 107). In other embodiments, the conductive material 208 of the inductor 223 may be deposited in the interposer 220 before the interposer 220 is mounted to a substrate; in such embodiments, the conductive material 208 may be protected (e.g., by a mask or blocking material) during further processing of the substrate. In some embodiments, more or fewer conductive contacts 222, 266 and/or more or less conductive material 208 may be included (e.g., based on the number and arrangement of conductive contacts 222, 266 or inductors 223, or based on design specifications (e.g., power or voltage delivery specifications) of a microelectronic assembly 100 including the interposer 220).

FIG. 2D illustrates a cross-section of an interposer 230 having conductive material 208 and an insulating material 252 therein, where a portion of the conductive material 208 and the insulating material 252 are arranged to form an electrical component, and in particular, a capacitor 232. The capacitor 232 may be a deep trench metal-insulator-metal (MIM) capacitor, where the insulating material 252 is between two layers of the conductive material 208 (e.g., a metal), referred to as plates. In this example, each plate of the capacitor 232 is coupled to a respective conductive contact 266 or 222 (e.g., which may be the same as the conductive contacts 266, 222 of FIG. 2A). In some embodiments, more or fewer conductive contacts 222, 266 and/or more or less conductive material 208 may be included (e.g., based on the number and arrangement of conductive contacts 222, 266 or capacitors 232, or based on design specifications (e.g., power or voltage delivery specifications) of a microelectronic assembly 100 including the interposer 230).

FIG. 3 illustrates one example process 300 that may be used to manufacture the microelectronic assembly 100. FIGS. 4A-4G are side, cross-sectional views of various stages in the example process 300. Although the operations discussed below with reference to FIGS. 3 and 4 (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 3 and 4 may be modified in accordance with the present disclosure to fabricate others of microelectronic assembly 100 disclosed herein.

At 305 of FIG. 3, a core is provided. FIG. 4A illustrates an assembly including a core 416, which may be the same as the core 116 shown in FIG. 1. The core may include a core material 410, which may be the same as the core material 110 of FIG. 1. One or more further layers 411 including a further layer material 417 may be coupled to the core 416. The one or more further layers 411 and further layer material 417 may be the same as the further layers 111 and further layer material 117 of FIG. 1. In this example, the core 416 and further layers 411 include conductive features formed from a conductive material 408 (e.g., conductive lines, traces, pads, contacts, vias, etc.). The conductive material 408 may be the same as the conductive material 108 of FIG. 1.

At 310 of FIG. 3, a preliminary substrate is formed over the core. FIG. 4B illustrates the assembly of FIG. 4A after forming a preliminary substrate 407 over the core 416. The preliminary substrate 407 may include a dielectric material 412, which may be the same as the dielectric material 112 of FIG. 1. The preliminary substrate 407 may include the same or similar conductive features formed from a conductive material 408 as described above for the core 416. The preliminary substrate 407 includes a first preliminary substrate face 407A (e.g., bottom or back preliminary substrate face), and a second preliminary substrate face 407B (e.g., top or front preliminary substrate face). In other embodiments, the preliminary substrate 407 may be placed over the core 416 (e.g., the preliminary substrate 407 being a pre-formed preliminary substrate), and may be attached to the core 416 (e.g., using an adhesive or another means).

At 315 of FIG. 3, a cavity is formed in the preliminary substrate. FIG. 4C illustrates the assembly of FIG. 4B after forming a cavity 419 in the preliminary substrate 407. The cavity 419 may be formed using any suitable means. For example, the cavity 419 may be formed by drilling, cutting, laser ablating, or chemically etching the preliminary substrate 407, and/or otherwise removing a portion of the preliminary substrate 407. In particular, the cavity 419 is formed in the second preliminary substrate face 407B (e.g., top or front preliminary substrate face) of the preliminary substrate 407. As shown, after formation of the cavity 419, conductive contacts 470 (e.g., conductive features in the preliminary substrate 407 including the conductive material 408) in the cavity 419 may be exposed (e.g., at a bottom of the cavity 419).

At 320 of FIG. 3, a bridge component and an interposer are joined. FIG. 4D illustrates a bridge component 414-1 being joined to an interposer 462. The bridge component 414-1 may be the same as or similar to the bridge die 114-1 of FIG. 1. As shown in FIG. 4D, the bridge component 414-1 may include a first bridge component face 414-1A (e.g., bottom or back bridge component face) and a second bridge component face 414-1B (e.g., top or front bridge component face). Conductive contacts 422-1 may be along the first bridge component face 414-1A, and conductive contacts 424 may be along the second bridge component face 414-1B.

The interposer 462 may be the same as or similar to the interposer 162 of FIG. 1. The interposer 462 may include an interposer material 464, which may be the same as the interposer material 164 of FIG. 1. The interposer may include a first interposer face 462A (e.g., bottom or back interposer face) and a second interposer face 462B (e.g., top or front interposer face). Conductive contacts 466 (e.g., including conductive contacts 466A, 466B) may be along the first interposer face 462A, and conductive contacts 422-2 may be along the second interposer face 462B. The conductive contacts 422-2, 466 may include the same conductive material 408 as the conductive material 108 of FIG. 1.

Joining the bridge component 414-1 and the interposer 462 may include joining conductive contacts 422-1 (e.g., along the first bridge component face 414-1A) and conductive contacts 422-2 (e.g., along the second interposer face 462B), forming joint conductive contacts 422 (e.g., including joint conductive contacts 422A, 422B, 422C, 422D). The bridge component 414-1 and interposer 462 (e.g., via the conductive contacts 422-1 and 422-2) may be bonded using any suitable technique, including direct bonding, hybrid bonding, solder bonding, and so on. Direct bonding includes metal-to-metal bonding techniques, e.g., copper-to-copper bonding, or other techniques in which bonding contacts of opposing bonding interfaces are brought into contact first, then subject to heat and compression. Hybrid bonding includes techniques in which bonding dielectric of opposing bonding interfaces, possibly first subjected to prior surface activation, are brought into contact first, then subject to heat and sometimes compression, or techniques in which the bonding contacts and the bonding dielectric, possibly first subjected to prior surface activation, of opposing bonding interfaces are brought into contact substantially simultaneously, and the subject to heat and sometimes compression.

Thus, hybrid bonding includes both metal-to-metal bonding at the bonding contacts as well as dielectric-to-dielectric bonding in regions between the contacts. The materials of opposing bonding dielectrics can be homogeneous (i.e., have substantially the same material composition) or non-homogeneous (i.e., have different material compositions).

In some embodiments, the bridge component 414-1 and the interposer 462 may be joined in an interposer-to-wafer assembly technique in which interposers are joined to a wafer that includes bridge components (e.g., bridge dies), and the wafer is subsequently singulated. In some embodiments, the bridge component 414-1 and the interposer 462 may be joined in a bridge-to-wafer assembly technique in which bridge components are joined to a wafer that includes interposers, and the water is subsequently singulated. In some embodiments, the bridge component 414-1 and the interposer 462 may be joined in a wafer-to-wafer assembly technique in which a wafer that includes bridge components (e.g., bridge dies) is joined to a wafer that includes interposers, and the wafers are subsequently singulated. In some embodiments, the bridge component 414-1 and the interposer 462 may be joined in an interposer-to-bridge component assembly technique in which individual interposers and bridge components are joined (e.g., outside of a wafer). In some embodiments, the process 300 does not include the joining of the bridge component 414-1 and the interposer 462 (e.g., 320 of FIG. 3), and a pre-joined bridge component 414-1 and interposer 462 are provided for placement in the cavity. In some embodiments, the interposer 462 may be placed in the cavity 419 (as described further below), and then the bridge component 414-1 may be joined to the interposer 462 in the cavity 419.

At 325 of FIG. 3, the bridge component and the interposer are placed in the cavity. FIG. 4E illustrates the placement of a bridge component 414-1 and an interposer 462 (e.g., the bridge component 414-1 and the interposer 462 joined as described above) in the cavity 419 (e.g., the cavity 419 shown in FIG. 4C). ITS interconnects 468 may be formed over the conductive contacts 470 in the preliminary substrate 407. The ITS interconnects 468 may be the same as the ITS interconnects 168 of FIG. 1, and the ITS interconnects 468 may include an interconnect material 429 which may be the same as the interconnect material 129 of FIG. 1.

The bridge component 414-1 and interposer 462 are lowered into the cavity 419 such that the conductive contacts 466 (e.g., including conductive contacts 466A, 466B) are placed over the ITS interconnects 468. An underfill layer 472 (e.g., the same as the underfill layer 172 described above with reference to FIG. 1, and including an underfill material 427 which may be the same as the underfill material 127) may be deposited around the ITS interconnects 468 between the interposer 462 and the preliminary substrate 407 (e.g., the surface of the preliminary substrate 407 along which the conductive contacts 470 are present). Before, during, or after the deposition of the underfill layer 472, the conductive contacts 466 and conductive contacts 470 may be joined via the ITS interconnects 468 (e.g., reflow processing of solder in the interconnect material 429 of the ITS interconnects 468). The method of joining of the conductive contacts 466 and the conductive contacts 470 is simply illustrative, and other methods may be used to join the conductive contacts 466 and conductive contacts 470 (for example, direct bonding or hybrid bonding, as described above). In some embodiments, the ITS interconnects 468 and/or underfill layer 472 may not be present. After placement of the bridge component 414-1 and the interposer 462 in the cavity 419, as shown, the second bridge component face 414-1B may be substantially level or flush with the second preliminary substrate face 407B. In other embodiments, the second bridge component face 414-1B may be lower than or higher than (along the z-axis as shown in FIG. 4E) the second preliminary substrate face 407B.

Although FIG. 4E shows that the ITS interconnects 468 may be formed over the conductive contacts 470 in the preliminary substrate 407, and that the conductive contacts 466 may be placed over the ITS interconnects 468, in some embodiments, the ITS interconnects 468 may be formed over the conductive contacts 466, and the bridge component 414-1 and interposer 462 may be lowered into the cavity 419 such that the ITS interconnects 468 are placed over the conductive contacts 470.

At 330 of FIG. 3, dielectric material is deposited into the cavity. FIG. 4F illustrates the assembly of FIG. 4E (e.g., the lower portion of FIG. 4E), after dielectric material is deposited into the cavity 419. The deposited dielectric material may be the same material as the dielectric material 412. As shown in FIG. 4F, the deposited dielectric material may fill the cavity 419 and surround, encapsulate, or enclose the bridge component 414-1, interposer 462, and conductive contacts 424 along the second bridge component face 414-1B. The conductive contacts 424 may be exposed at the second preliminary substrate face 407B. In some embodiments, the second preliminary substrate face 407B may be planarized using chemical-mechanical polishing (CMP) or any other suitable process to expose the conductive contacts 424 (e.g., after the dielectric material is deposited into the cavity 419).

At 335 of FIG. 3, one or more electronic components are joined to the bridge component (optionally after one or more additional layers or materials are placed over the preliminary substrate, such as a build-up dielectric and/or additional conductive material). At 340 of FIG. 3, a package substrate is joined to the preliminary substrate (optionally after one or more additional layers or materials are placed over the preliminary substrate, such as a build-up dielectric and/or additional conductive material). FIG. 4G illustrates the assembly of FIG. 4F after joining one or more electronic components (here, two dies 414-2, 414-3) to the bridge component 414-1. In particular, DTS interconnects 440 (e.g., the same as the DTS interconnects 140 shown in FIG. 1) comprising an interconnect material (e.g., the same as the interconnect material 429 described above) and DTD interconnects 430 (e.g., the same as the DTD interconnects 130 described above with respect to FIG. 1) comprising a conductive material (e.g., the same as the interconnect material 429) are deposited. The DTS interconnects 440 and the DTD interconnects 430 may be deposited and processed as appropriate (e.g., for solder-based interconnects, subjected to thermal reflow) to join conductive features along the second preliminary substrate face 407B (e.g., conductive lines, traces, pads, contacts, vias, etc. of conductive material 408 in the preliminary substrate 407 and conductive contacts 424 along the second bridge component face 414-1B) with conductive contacts 421 on the bottom surfaces of the dies 414-2, 414-3. An underfill layer 441 (e.g., the same as the underfill layer 141 of FIG. 1) may be deposited around the DTS interconnects 440 and the DTD interconnects 430 between the second preliminary substrate face 407B and the dies 414-2, 414-3. FIG. 4G further illustrates the assembly after a package substrate 402 (e.g., the same as or similar to the package substrate 102 shown in FIG. 1) is joined to the assembly. STPS interconnects 450 (e.g., the same as or similar to the STPS interconnects 150 shown in FIG. 1) comprising an interconnect material (e.g., the interconnect material 429 described above) may be deposited and processed as appropriate (e.g., for solder-based interconnects, subjected to thermal reflow) to join the preliminary substrate 407 with the package substrate 402. In particular, conductive features along the first preliminary substrate face 407A (e.g., conductive lines, traces, pads, contacts, vias, etc. of conductive material 408 in the preliminary substrate 407) may be joined (e.g., via the conductive features in the core 416 and/or further layers 411, conductive contacts 444, and STPS interconnects 450) to conductive contacts 446 of the package substrate. An underfill layer 428 (e.g., the same as or similar to the underfill layer 128 of FIG. 1, and including an underfill material which may be the same as the underfill material 427 described above) may be deposited around the STPS interconnects 450 between the preliminary substrate 407 and the package substrate 402 (e.g., between the core 416 or further layers 411 and the package substrate 402).

The microelectronic assemblies disclosed herein may be included in any suitable electronic component. FIGS. 5-8 illustrate various examples of apparatuses that may include, or be included in, any of the microelectronic assemblies disclosed herein.

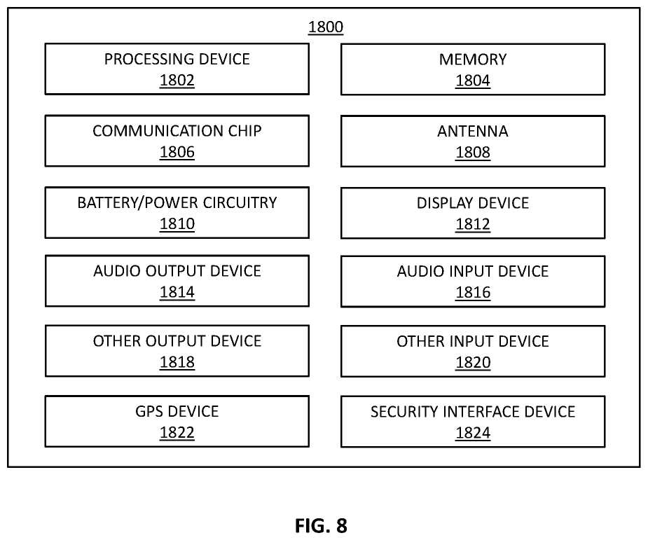

FIG. 5 is a top view of a wafer 1500 and dies 1502 that may be included in any of the microelectronic assemblies disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 6, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies disclosed herein may be manufactured using a die-to-wafer assembly technique in which some dies 114 are attached to a wafer 1500 that include others of the dies 114, and the wafer 1500 is subsequently singulated.

FIG. 6 is a cross-sectional side view of an IC device 1600 that may be included in any of the microelectronic assemblies disclosed herein (e.g., in any of the dies 114). One or more of the IC devices 1600 may be included in one or more dies 1502 (FIG. 5). The IC device 1600 may be formed on a die substrate 1602 (e.g., the wafer 1500 of FIG. 5) and may be included in a die (e.g., the die 1502 of FIG. 5). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 5) or a wafer (e.g., the wafer 1500 of FIG. 5).

The IC device 1600 may include one or more device layers 1604 disposed on the die substrate 1602. The device layer 1604 may include features of one or more transistors 1640 (e.g., metal-oxide-semiconductor field effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 6 and may include a wide variety of other types and configurations such as, for example, planar transistors, non-planar transistors, or a combination of both. Non-planar transistors may include fin field effect transistors (FinFETs), such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a P-type metal-oxide-semiconductor (PMOS) or a N-type metal-oxide-semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching processes. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 6 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 6. Although a particular number of interconnect layers 1606-1610 is depicted in FIG. 6, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 6. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 6. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 6, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the bridge die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the bridge die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

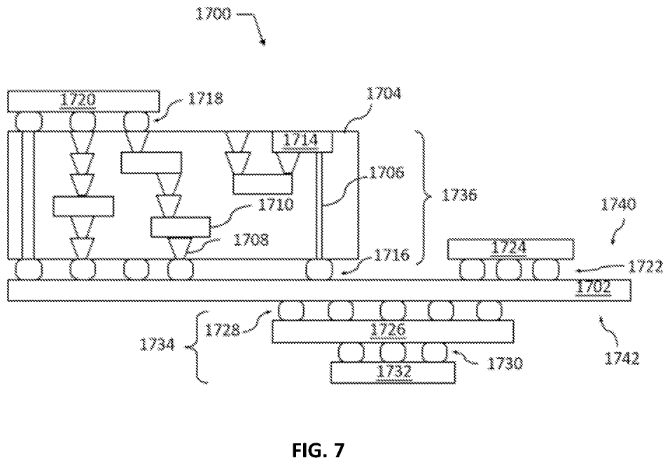

FIG. 7 is a cross-sectional side view of an IC device assembly 1700 that may include any of the microelectronic assemblies disclosed herein. In some embodiments, the IC device assembly 1700 may be the microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 5), an IC device (e.g., the IC device 1600 of FIG. 6), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. As illustrated in FIG. 7, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more of the microelectronic assemblies disclosed herein. For example, any suitable ones of the components of the electrical device 1800 may include one or more of the IC device assemblies 1700, IC devices 1600, or dies 1502 disclosed herein, and may be arranged in any of the microelectronic assemblies disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1812, but may include display device interface circuitry (e.g., a connector and driver circuitry) to which a display device 1812 may be coupled. In another set of examples, the electrical device 1800 may not include an audio input device 1816 or an audio output device 1814, but may include audio input or output device interface circuitry (e.g., connectors and supporting circuitry) to which an audio input device 1816 or audio output device 1814 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1806 (e.g., one or more communication chips). For example, the communication chip 1806 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as Worldwide Interoperability for Microwave Access (WiMAX) networks, which is a certification mark for products that pass conformity and interoperability tests for the IEEE 802.16 standards. The communication chip 1806 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The electrical device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as global positioning system (GPS), EDGE, GPRS, CDMA, WiMAX, LTE, EV-DO, or others. In some embodiments, a first communication chip 1806 may be dedicated to wireless communications, and a second communication chip 1806 may be dedicated to wired communications.

The electrical device 1800 may include battery/power circuitry 1810. The battery/power circuitry 1810 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display.

The electrical device 1800 may include an audio output device 1814 (or corresponding interface circuitry, as discussed above). The audio output device 1814 may include any device that generates an audible indicator, such as speakers, headsets, or earbuds.

The electrical device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The electrical device 1800 may include a GPS device 1822 (or corresponding interface circuitry, as discussed above). The GPS device 1822 may be in communication with a satellite-based system and may receive a location of the electrical device 1800, as known in the art.

The electrical device 1800 may include a security interface device 1824 (or corresponding interface circuitry, as discussed above). The security interface device 1824 may include any device that provides security features for the electrical device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The electrical device 1800 may include an other output device 1818 (or corresponding interface circuitry, as discussed above). Examples of the other output device 1818 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.

Example 1 provides an assembly, including a substrate; a die at least partially in the substrate; and an interposer in the substrate, the interposer including a first interposer face; a second interposer face opposite the first interposer face, the second interposer face coupled to the die; a first set of conductive features along the first interposer face; and a second set of conductive features along the second interposer face, where the second set of conductive features has a greater number of conductive features than the first set of conductive features.

Example 2 provides the assembly of example 1, where the first set of conductive features corresponds to a first number of voltages, the second set of conductive features corresponds to a second number of voltages, and the first number of voltages is different from the second number of voltages.

Example 3 provides the assembly of examples 1 or 2, where the second set of conductive features corresponds to a set of voltages, and a number of conductive features in the first set of conductive features is equal to a number of voltages in the set of voltages.

Example 4 provides the assembly of any one of examples 1-3, where the die is a bridge die.

Example 5 provides the assembly of example 4, where one of the second set of conductive features is coupled to a conductive feature in the bridge die.

Example 6 provides the assembly of examples 4 or 5, further including an additional die over the bridge die, the additional die electrically coupled to one of the second set of conductive features via the bridge die.

Example 7 provides the assembly of any one of examples 1-6, where one of the first set of conductive features is joined to a conductive feature in the substrate.

Example 8 provides the assembly of any one of examples 1-7, where the interposer includes power management circuitry.

Example 9 provides the assembly of example 8, where the power management circuitry includes voltage regulation circuitry.

Example 10 provides the assembly of examples 8 or 9, where the power management circuitry includes at least one of a capacitor, an inductor, and a resistor.

Example 11 provides the assembly of any one of examples 1-10, where the interposer includes glass.

Example 12 provides the assembly of example 11, where the glass includes one or more of a soda-lime glass, a borosilicate glass, an aluminosilicate glass, an alkali borosilicate glass, an aluminoborosilicate glass, and an alkali aluminosilicate glass.

Example 13 provides the assembly of any one of examples 1-10, where the interposer includes a semiconductor material.

Example 14 provides the assembly of any one of examples 1-10, where the semiconductor material includes gallium and nitrogen.

Example 15 provides the assembly of any one of examples 1-10, where the semiconductor material includes silicon.

Example 16 provides the assembly of example 15, where the semiconductor material further includes carbon.

Example 17 provides the assembly of any one of examples 1-16, where the interposer includes a redistribution layer.

Example 18 provides a semiconductor package, including a substrate; an interposer in the substrate, the interposer having a first face and a second face; a bridge die over the interposer; a first plurality of electrical connections coupling the interposer to the substrate, the first plurality of electrical connections along the first face of the interposer; and a second plurality of electrical connections coupling the interposer to the bridge die, the second plurality of electrical connections along the second face of the interposer, where the second plurality of electrical connections has a greater number of electrical connections than the first plurality of electrical connections.

Example 19 provides the semiconductor package of example 18, where the first plurality of electrical connections corresponds to a first number of voltages, the second plurality of electrical connections corresponds to a second number of voltages, and the first number of voltages is different from the second number of voltages.

Example 20 provides the semiconductor package of any one of examples 18 or 19, where the second plurality of electrical connections corresponds to a set of voltages, and a number of electrical connections in the first plurality of electrical connections is equal to a number of voltages in the set of voltages.

Example 21 provides the semiconductor package of any one of examples 18-20, where one of the second plurality of electrical connections is coupled to a conductive feature in the bridge die.

Example 22 provides the semiconductor package of any one of examples 18-21, further including an electronic component (such as an additional die) over the bridge die, the electronic component electrically coupled to one of the second plurality of electrical connections via the bridge die.

Example 23 provides the semiconductor package of any one of examples 18-22, where one of the first plurality of electrical connections is joined to a conductive feature in the substrate.

Example 24 provides an assembly, including a substrate; a die at least partially embedded in the substrate; an interposer embedded in the substrate, the interposer coupled to the die; a first plurality of conductive features between the die and the interposer; and a second plurality of conductive features between the interposer and the substrate, the second plurality of conductive features at an opposite side of the interposer from the first plurality of conductive features, where a width of a first conductive feature in the first plurality of conductive features is less than a width of a second conductive feature in the second plurality of conductive features.

Example 25 provides the assembly of example 25, where a length of the first conductive feature is less than a length of the second conductive feature.

Example 26 provides the assembly of examples 24 or 25, where the first plurality of conductive features corresponds to a first number of voltages, the second plurality of conductive features corresponds to a second number of voltages, and the first number of voltages is different from the second number of voltages.

Example 27 provides the assembly of any one of examples 24-26, where the first plurality of conductive features corresponds to a plurality of voltages, and a number of conductive features in the second plurality of conductive features is equal to a number of voltages in the plurality of voltages.

Example 28 provides the assembly of any one of examples 24-26, where a first conductive feature in the first plurality of conductive features corresponds to a first voltage, a second conductive feature in the second plurality of conductive features corresponds to a second voltage, the second conductive feature electrically joined to the first conductive feature, and the first voltage is less than the second voltage.

Example 29 provides the assembly of any one of examples 24-26, where the second plurality of conductive features corresponds to a plurality of voltages, the plurality of voltages including a ground voltage and a non-ground voltage.

Example 30 provides the assembly of any one of examples 24-26, where the second plurality of conductive features corresponds to a plurality of voltages, the plurality of voltages including a ground voltage, a first non-ground voltage, and a second non-ground voltage, the second non-ground voltage higher than the first non-ground voltage.

Example 31 provides the assembly of any one of examples 24-26, where the second plurality of conductive features corresponds to a plurality of voltages, at least one voltage in the plurality of voltages greater than or equal to 3V.

Example 32 provides the assembly of example 31, where at least voltage in the plurality of voltages is greater than or equal to 5V.

Example 33 provides the assembly of any one of examples 24-32, further including an electronic component (such as an additional die) over the die, the electronic component electrically coupled to one of the first set of conductive features via the die.

1. An assembly, comprising:
a substrate;
a die at least partially in the substrate; and
an interposer in the substrate, the interposer comprising:
a first interposer face;
a second interposer face opposite the first interposer face, the second interposer face coupled to the die;
a first set of conductive features along the first interposer face; and
a second set of conductive features along the second interposer face, wherein the second set of conductive features has a greater number of conductive features than the first set of conductive features.

2. The assembly of claim 1, wherein the die is a bridge die.

3. The assembly of claim 2, wherein one of the second set of conductive features is coupled to a conductive feature in the bridge die.

4. The assembly of claim 2, further comprising an additional die over the bridge die, the additional die electrically coupled to one of the second set of conductive features via the bridge die.

5. The assembly of claim 1, wherein one of the first set of conductive features is joined to a conductive feature in the substrate.

6. The assembly of claim 1, wherein the interposer comprises power management circuitry.

7. The assembly of claim 6, wherein the power management circuitry comprises voltage regulation circuitry.

8. The assembly of claim 6, wherein the power management circuitry comprises at least one of a capacitor, an inductor, and a resistor.

9. The assembly of claim 1, wherein the interposer comprises glass.

10. The assembly of claim 1, wherein the interposer comprises gallium and nitrogen.

11. The assembly of claim 1, wherein the interposer comprises silicon.

12. The assembly of claim 11, wherein the interposer further comprises carbon.

13. The assembly of claim 1, wherein the interposer comprises a redistribution layer.

14. A semiconductor package, comprising:
a substrate;
an interposer in the substrate, the interposer having a first face and a second face;
a bridge die over the interposer;
a first plurality of electrical connections coupling the interposer to the substrate, the first plurality of electrical connections along the first face of the interposer; and
a second plurality of electrical connections coupling the interposer to the bridge die, the second plurality of electrical connections along the second face of the interposer, wherein the second plurality of electrical connections has a greater number of electrical connections than the first plurality of electrical connections.

15. The semiconductor package of claim 14, wherein one of the second plurality of electrical connections is coupled to a conductive feature in the bridge die.

16. The semiconductor package of claim 14, further comprising an electronic component over the bridge die, the electronic component electrically coupled to one of the second plurality of electrical connections via the bridge die.

17. The semiconductor package of claim 14, wherein one of the first plurality of electrical connections is joined to a conductive feature in the substrate.

18. An assembly, comprising:
a substrate;
a die at least partially embedded in the substrate;
an interposer embedded in the substrate, the interposer coupled to the die;
a first plurality of conductive features between the die and the interposer; and
a second plurality of conductive features between the interposer and the substrate, the second plurality of conductive features at an opposite side of the interposer from the first plurality of conductive features, wherein a width of a first conductive feature in the first plurality of conductive features is less than a width of a second conductive feature in the second plurality of conductive features.

19. The assembly of claim 18, wherein a length of the first conductive feature is less than a length of the second conductive feature.

20. The assembly of claim 18, further comprising an electronic component over the die, the electronic component electrically coupled to one of the first plurality of conductive features via the die.
